(19) United States
(12) Patent Application Publication
(10) Pub. No.: US 2026/0165014 A1
(43) Pub. Date: Jun. 11, 2026

(54) DISPLAY DEVICE

(71) Applicant: Magnolia White Corporation, Tokyo (JP)

(72) Inventors: Takamitsu FUJIMOTO, Tokyo (JP); Hiroshi TABATAKE, Tokyo (JP); Sho YANAGISAWA, Tokyo (JP)

(73) Assignee: Magnolia White Corporation, Tokyo (JP)

(21) Appl. No.: 19/409,824

(22) Filed: Dec. 5, 2025

(30) Foreign Application Priority Data
Dec. 5, 2024 (JP) 2024-212513

(51) Int. Cl. H10K 59/88; H10K 59/122; H10K 59/124; H10K 59/126

(52) U.S. Cl. CPC H10K 59/88; H10K 59/122; H10K 59/124; H10K 59/126

(57) ABSTRACT

According to one embodiment, a display device includes a substrate including a display area and a dummy pixel area which includes a plurality of dummy subpixels, a plurality of lower electrodes located above the substrate and provided in the dummy pixel area, and a partition which includes a lower portion provided above the lower electrode and an upper portion provided on the lower portion to protrude from a side surface of the lower portion, and which is provided across the display area and the dummy pixel area. Each of the plurality of dummy subpixels includes the lower electrode. The partition includes a first aperture overlapping with the lower electrode. At least a part of the plurality of lower electrodes includes a second aperture overlapping with the first aperture.

### CROSS-REFERENCE TO RELATED APPLICATION

This application is based upon and claims the benefit of priority from Japanese Patent Application No. 2024-212513, filed Dec. 5, 2024, the entire contents of which are incorporated herein by reference.

### FIELD

Embodiments described herein relate generally to a display device.

### BACKGROUND

Recently, display devices in which organic light emitting diodes (OLED) are applied as display elements have been put to practical use. In this type of display devices, a technique for improving the yield is required.

### BRIEF DESCRIPTION OF THE DRAWINGS

FIG. 1 is a view showing a configuration example of a display device according to a first embodiment.

FIG. 2 is a schematic plan view showing an example of a layout of subpixels.

FIG. 3 is a schematic cross-sectional view showing the display device along III-III line in FIG. 2.

FIG. 4 is a schematic plan view showing an inorganic insulating layer in a pixel.

FIG. 5 is a schematic cross-sectional view showing the display device along V-V line in FIG. 4.

FIG. 6 is a schematic cross-sectional view showing the display device along VI-VI line in FIG. 4.

FIG. 7 is a schematic cross-sectional view showing a structure around a slit.

FIG. 8 is a schematic top view showing the display device including a cover member.

FIG. 9 is an enlarged plan view showing an area surrounded by frame IX in FIG. 8, in the display device according to the first embodiment.

FIG. 10 is a schematic plan view showing two dummy pixels arranged in an X-direction, in the display device according to the first embodiment.

FIG. 11 is a schematic cross-sectional view showing the display device along XI-XI line in FIG. 10.

FIG. 12 is an enlarged plan view showing an aperture.

FIG. 13 is a schematic cross-sectional view showing the display device along XIII-XIII line in FIG. 12.

FIG. 14 is a schematic plan view showing a display device according to a comparative example.

FIG. 15 is an enlarged plan view showing an area surrounded by frame IX in FIG. 8, in a display device according to a second embodiment.

FIG. 16 is a schematic plan view showing two dummy pixels arranged in an X-direction, in the display device according to the second embodiment.

### DETAILED DESCRIPTION

In general, according to one embodiment, a display device includes a substrate including a display area where images are displayed, and a dummy pixel area which includes a plurality of dummy subpixels where images are not displayed, which surrounds the display area, and which is adjacent to the display area, a plurality of lower electrodes located above the substrate and provided in the dummy pixel area, and a partition which includes a lower portion provided above the lower electrode and an upper portion provided on the lower portion to protrude from a side surface of the lower portion, and which is provided across the display area and the dummy pixel area. Each of the plurality of dummy subpixels includes the lower electrode. The partition includes a first aperture overlapping with the lower electrode. At least a part of the plurality of lower electrodes includes a second aperture overlapping with the first aperture.

According to another embodiment, a display device includes a substrate having a display area where images are displayed and a surrounding area provided outside the display area, a conductive layer located above the substrate and provided in the surrounding area, and a partition which includes a lower portion provided above the conductive layer, and an upper portion provided on the lower portion to protrude from a side surface of the lower portion, and which is provided across the display area and the surrounding area. The partition includes a first aperture overlapping with the conductive layer. The conductive layer includes a second aperture overlapping with the first aperture.

According to the embodiments, a display device capable of improving a yield can be provided.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

Incidentally, in the figures, an X-axis, a Y-axis, and a Z-axis orthogonal to each other are described to facilitate understanding as needed. A direction along the X-axis is referred to as an X-direction, a direction along the Y-axis is referred to as a Y-direction, and a direction along the Z-axis is referred to as a Z-direction. In addition, viewing various elements parallel to the Z-direction is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

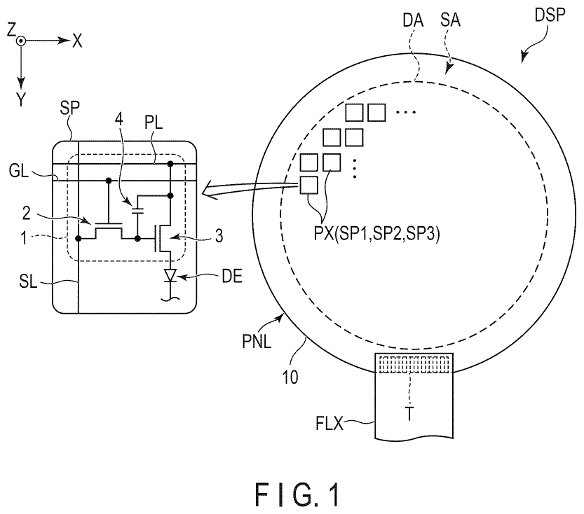

FIG. 1 is a diagram showing a configuration example of a display device DSP according to a first embodiment. The display device DSP comprises a display panel PNL including an insulating substrate 10. The substrate 10 has a display area DA where images are displayed, and a surrounding area SA around the display area DA. The substrate 10 may be glass or a resinous film having flexibility.

In the present embodiment, the substrate 10 has a circular shape in plan view. However, the shape of the substrate 10 in plan view is not limited to a circular shape, but may be the other shape such as a rectangle, a square, or an oval.

The display area DA includes a plurality of pixels PX arrayed in a matrix in the X-direction and the Y-direction. Each pixel PX includes a plurality of subpixels SP which display different colors. In the present embodiment, it is assumed that each pixel PX includes a green subpixel SP1, a blue subpixel SP2, and a red subpixel SP3. However, each pixel PX may include a subpixel SP which exhibits the other color such as white in addition to the subpixels SP1, SP2, and SP3 or instead of one of subpixels SP1, SP2, and SP3.

The display device DSP further comprises a terminal portion T provided in the surrounding area SA. A flexible printed circuit FLX which applies voltages and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements consisting of thin-film transistors.

A plurality of scanning lines GL which supply a scanning signal to the pixel circuit 1 of each subpixel SP, a plurality of signal lines SL which supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to a scanning line GL. The source electrode of the pixel switch 2 is connected to a signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

Incidentally, the configuration of the pixel circuit 1 is not limited to the example shown in the figure. For example, the pixel circuit 1 may comprise more thin-film transistors and more capacitors.

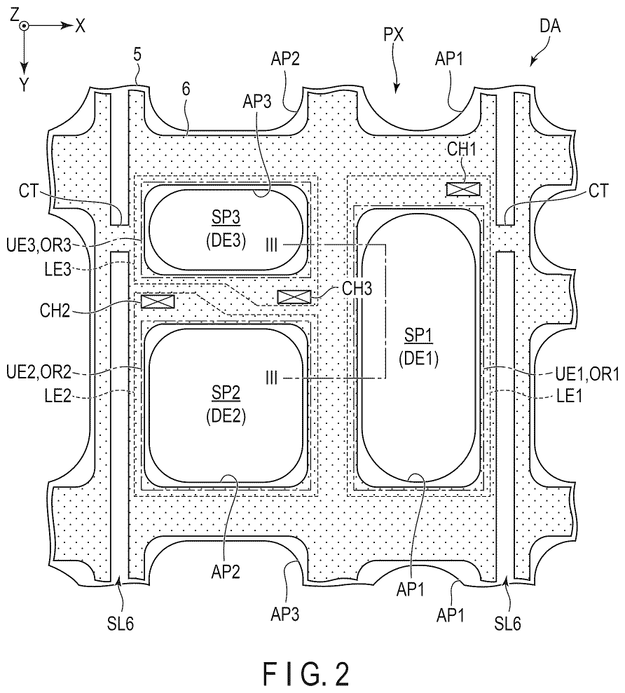

FIG. 2 is a schematic plan view showing an example of a layout of subpixels SP1, SP2, and SP3. In the example of FIG. 2, each of the subpixels SP2 and SP3 is arranged with the subpixel SP1 in the X-direction. Furthermore, the subpixels SP2 and SP3 are arranged in the Y-direction.

When the subpixels SP1, SP2, and SP3 are provided on this layout, a column in which the subpixels SP2 and SP3 are alternately provided in the Y-direction and a column in which a plurality of subpixels SP1 are repeatedly provided in the Y-direction are formed, in the display area DA. These columns are alternately arranged in the X-direction. Incidentally, the layout of the subpixels SP1, SP2, and SP3 is not limited to the example of FIG. 2.

A rib layer 5 is provided in the display area DA. The rib layer 5 includes pixel apertures AP1, AP2, and AP3 in the subpixels SP1, SP2, and SP3, respectively. In the example of FIG. 2, the pixel apertures AP1 and AP2 are larger than the pixel aperture AP3. Incidentally, the size and shape of the pixel apertures AP1, AP2, and AP3 are not limited to the examples illustrated.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

The parts of the lower electrode LE1, the upper electrode UE1, and the organic layer OR1, which overlap with the pixel aperture AP1, constitute the display element DE1 of the subpixel SP1. The parts of the lower electrode LE2, the upper electrode UE2, and the organic layer OR2, which overlap with the pixel aperture AP2, constitute the display element DE2 of the subpixel SP2. The parts of the lower electrode LE3, the upper electrode UE3, and the organic layer OR3, which overlap with the pixel aperture AP3, constitute the display element DE3 of the subpixel SP3. The display elements DE1, DE2, and DE3 may further include a cap layer to be described below. The rib layer 5 surrounds each of these display elements DE1, DE2 and DE3.

The lower electrode LE1 is connected to the pixel circuit 1 (see FIG. 1) of the subpixel SP1 through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3.

A conductive partition 6 is provided in the display area DA. The partition 6 is located above the rib layer 5 and overlaps with the rib layer 5 as a whole. In the example of FIG. 2, the partition 6 has the same planar shape as that of the rib layer 5. In other words, the partition 6 comprises an aperture in each of subpixels SP1, SP2, and SP3. From another viewpoint, each of the rib layer 5 and the partition 6 has a grating shape in plan view, and surrounds each of the display elements DE1, DE2, and DE3. In addition, the partition 6 surrounds the pixel apertures AP1, AP2, and AP3. The partition 6 functions as lines which apply a common voltage to the upper electrodes UE1, UE2, and UE3.

The partition 6 includes a plurality of slits SL6. In the example of FIG. 2, each of the slits SL6 extends in the Y-direction. For example, the subpixels SP1, SP2, and SP3 constituting one pixel PX is provided between two slits SL6 that are adjacent to each other in the X-direction. Furthermore, the partition 6 includes connecting portions CT which connect parts divided by the slits SL6. Incidentally, the arrangement of the slits SL6 and the connecting portions CT is not limited to the example shown in FIG. 2. For example, slits SL6 continuous between both ends of the display area DA in the Y-direction may be provided.

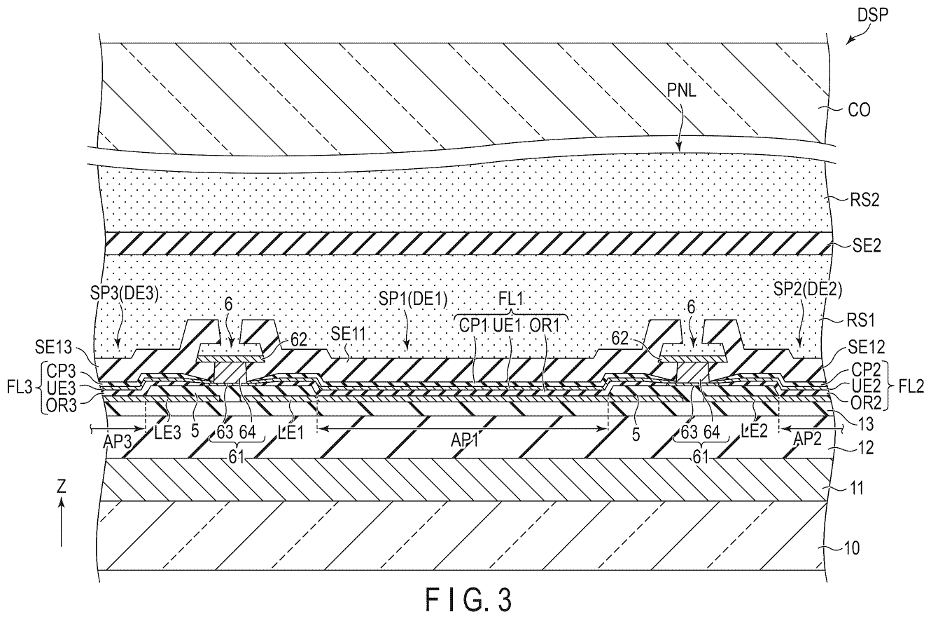

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuits 1, the scanning lines GL, the signal lines SL, and the power lines PL shown in FIG. 1. The circuit layer 11 is covered with an organic insulating layer 12. The organic insulating layer 12 functions as a planarization film which planarizes the irregularities formed by the circuit layer 11.

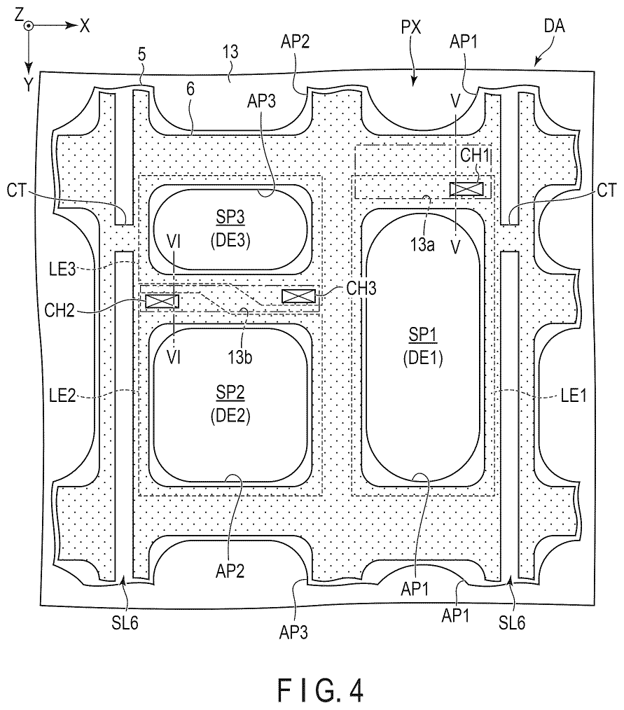

The organic insulating layer 12 is covered with the inorganic insulating layer 13. The lower electrodes LE1, LE2, and LE3 are provided on the inorganic insulating layer 13 and are spaced apart from each other. The inorganic insulating layer 13 is in contact with a lower surface of each of the lower electrodes LE1, LE2, and LE3. The rib layer 5 is provided on the inorganic insulating layer 13 and the lower electrodes LE1, LE2, and LE3. The end portions of the lower electrodes LE1, LE2, and LE3 are covered with the rib layer 5. Though not shown in the cross-section of FIG. 3, each of the lower electrodes LE1, LE2, and LE3 is connected to the pixel circuit 1 of the circuit layer 11 (drain electrode of the drive transistor 3 shown in FIG. 1) through apertures provided in the inorganic insulating layer 13 (apertures 13a and 13b shown in FIG. 4) and the contact holes CH1, CH2, and CH3 provided in the organic layer 12.

The partition 6 includes a conductive lower portion 61 provided on the rib layer 5, and an upper portion 62 provided on the lower portion 61. The upper portion 62 has a width greater than that of the lower portion 61. As a result, both end portions of the upper portion 62 protrude beyond side surfaces of the lower portion 61. This shape of the partition 6 is referred to as an overhang shape.

In the example of FIG. 3, the lower portion 61 has a bottom layer 63 provided on the rib layer 5 and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64. In addition, the end portion of the bottom layer 63 is located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers for improving the efficiency of extracting the light emitted from the organic layers OR1, OR2, and OR3, respectively.

In the following descriptions, a multilayer body including the organic layer OR1, the upper electrode UE1, and the cap layer CP1 is referred to as a stacked film FL1, a multilayer body including the organic layer OR2, the upper electrode UE2, and the cap layer CP2 is referred to as a stacked film FL2, and a multilayer body including the organic layer OR3, the upper electrode UE3, and the cap layer CP3 is referred to as a stacked film FL3.

Sealing layers SE11, SE12, and SE13 which cover the stacked films FL1, FL2, and FL3, are provided in the subpixels SP1, SP2, and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on this partition 6. In addition, the sealing layer SE11 located on the partition 6 between the subpixels SP1 and SP3 is spaced apart from the sealing layer SE13 located on this partition 6. However, two of the sealing layers SE11, SE12, and SE13 located above the partition 6 may be in contact with each other.

For example, a gap is formed between each of the sealing layers SE11, SE12 and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA as well. The display panel PNL includes each of the components located between the substrate 10 and the resin layer RS2.

A cover member CO is provided above the display panel PNL. This cover member CO is attached to the display panel PNL via, for example, an adhesive layer such as an optical clear adhesive (OCA). A member such as a polarizer may be provided between the cover member CO and the display panel PNL.

The organic insulating layer 12 is formed of an organic insulating material such as polyimide. Each of the rib layer 5, the inorganic insulating layer 13, and the sealing layers SE11, SE12, SE13, and SE2 is formed of an inorganic insulating material such as silicon nitride (SiNx), silicon oxide (SiOx) or silicon oxynitride (SiON). In one example, the rib layer 5 and the inorganic insulating layer 13 are formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 includes a reflective layer, and a pair of conductive oxide layers covering upper and lower surfaces of the reflective layer. The reflective layer can be formed of, for example, a metal material excellent in light reflectivity, such as silver. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2, and UE3 is formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the cap layers CP1, CP2 and CP3 has, for example, a multilayer structure in which a plurality of transparent layers are stacked. These transparent layers may include a layer formed of an inorganic material and a layer formed of an organic material. Moreover, these transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

Each of the bottom layer 63 and the stem layer 64 of the partition 6 is formed of, for example, a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may comprise a multilayer structure consisting of a plurality of layers. Alternatively, the stem layer 64 may include a layer formed of an insulating material.

For example, the upper portion 62 of the partition 6 has a multilayer structure consisting of a lower layer formed of a metal material and an upper layer formed of conductive oxide. For example, titanium, titanium nitride, molybdenum, tungsten, a molybdenum-tungsten alloy or a molybdenum-niobium alloy can be used as the metal material for forming the lower layer. For the conductive oxide forming the upper layer, for example, ITO or IZO can be used. Incidentally, the upper portion 62 may have a single-layer structure of a metal material. Furthermore, the upper portion 62 may include a layer formed of an insulating material.

A common voltage is applied to the partition 6. This common voltage is applied to each of the upper electrodes UE1, UE2, and UE3 that are in contact with the side surfaces of the lower portion 61. A pixel voltage is applied to the lower electrodes LE1, LE2, and LE3 through the pixel circuits 1 provided in the subpixels SP1, SP2, and SP3, respectively, based on the video signals of the signal lines SL.

In one example, the organic layers OR1, OR2, and OR3 are configured to emit light of colors different from each other. As another example, the light emitting layers of the organic layers OR1, OR2, and OR3 may emit light exhibiting the same color (for example, white). In this case, the display device DSP may comprise color filters which convert the light emitted from the light emitting layers included in the respective organic layers OR1, OR2, and OR3 into light of the colors corresponding to the subpixels SP1, SP2, and SP3. In addition, the display device DSP may comprise a layer including a quantum dot which generates light exhibiting colors corresponding to the subpixels SP1, SP2, and SP3 by the excitation caused by the light emitted from the light emitting layers.

FIG. 4 is a schematic plan view showing the inorganic insulating layer 13 in the pixel PX. A plurality of apertures 13a and 13b are provided in the inorganic insulating layer 13. In FIG. 4, each of the apertures 13a and 13b is represented by a double-dashed line.

The aperture 13a is provided between the subpixels SP1 that are adjacent in the Y-direction. The aperture 13a overlaps with the contact hole CH1 in plan view and also overlaps with a part of the lower electrode LE1 in plan view. The aperture 13b is provided between the subpixels SP2 and SP3 that are adjacent in the Y-direction in the pixel PX. The aperture 13b overlaps with each of the contact holes CH2 and CH3 in plan view and also overlaps with a part of each of the lower electrodes LE2 and LE3 in plan view.

A plurality of apertures 13a and 13b are provided in the entire display area DA. Incidentally, the apertures 13a or 13b may be provided or the apertures may be further provided in the inorganic insulating layer 13.

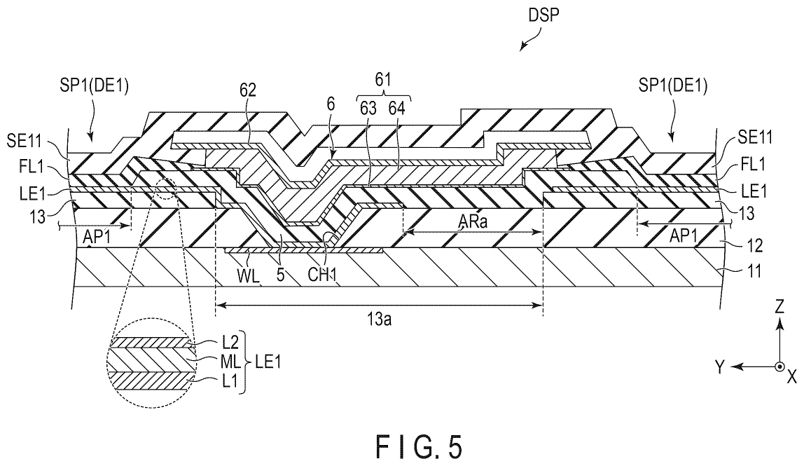

FIG. 5 is a schematic cross-sectional view showing the display device DSP along V-V line in FIG. 4. Incidentally, in FIG. 5, elements located under the circuit layer 11 and elements located above the sealing layers SE11, SE12, and SE13 are omitted.

The lower electrode LE1 is in contact with the organic insulating layer 12 through the aperture 13a. Incidentally, the lower electrode LE1 covers a part of the aperture 13a, but does not cover the entire aperture 13a. The lower electrode LE1 is in contact with a line WL included in the circuit layer 11 through the contact hole CH1 provided in the organic insulating layer 12. The line WL corresponds to, for example, the source electrode or the drain electrode of the drive transistor 3 shown in FIG. 1.

The rib layer 5 is in contact with the organic insulating layer 12 in an area ARa of the aperture 13a, which is not covered with the lower electrode LE1. The partition 6 covers the aperture 13a.

As shown and enlarged on the lower side of FIG. 5, the lower electrode LE1 includes the metal layer ML, a first layer L1 which covers a lower surface of the metal layer ML, and a second layer L2 which covers an upper surface of the metal layer ML. The metal layer ML is a reflective layer formed of, for example, silver. Each of the first layer L1 and the second layer L2 is a conductive oxide layer formed of, for example, a transparent conductive oxide such as ITO.

In one example, the thickness of the second layer L2 is smaller than the thickness of each of the first layer L1 and the metal layer ML. In addition, the thickness of the first layer L1 is smaller than or equal to the thickness of the metal layer ML. Incidentally, the relationship in thickness among the metal layer ML and each of the first layer L1 and the second layer L2 is not limited to the above-mentioned example. For example, the thickness of the second layer L2 may be greater than the thickness of each of the first layer L1 and the metal layer ML.

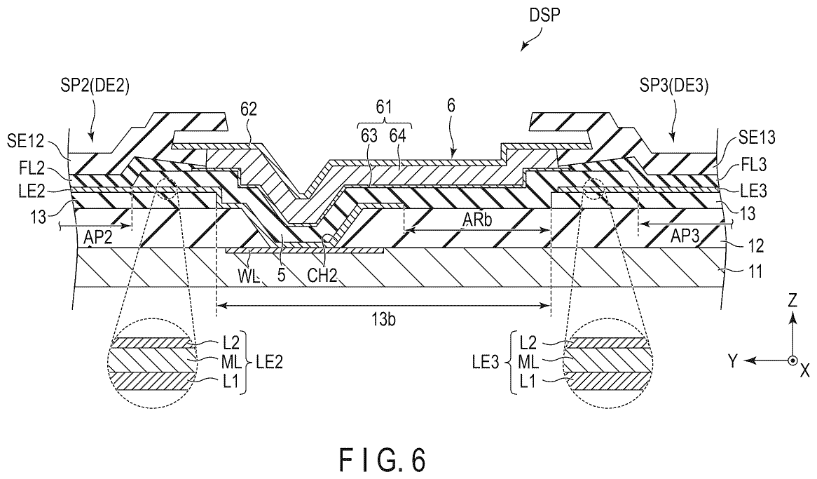

FIG. 6 is a schematic cross-sectional view showing the display device DSP along VI-VI line shown in FIG. 4. Incidentally, in FIG. 6, elements located under the circuit layer 11 and elements located above the sealing layers SE11, SE12, and SE13 are omitted. The lower electrode LE2 is in contact with the organic insulating layer 12 through the aperture 13b. Incidentally, the lower electrode LE2 covers a part of the aperture 13b, but does not cover the entire aperture 13b. The lower electrode LE2 is in contact with the line WL included in the circuit layer 11 through the contact hole CH2 provided in the organic insulating layer 12.

Although not shown in the figure, the lower electrode LE3 is configured in the same manner as the lower electrode LE2. In other words, the lower electrode LE3 is in contact with the organic insulating layer 12 through the aperture 13b. In addition, the lower electrode LE3 is in contact with the line WL through the contact hole CH3 provided in the organic insulating layer 12.

The rib layer 5 is in contact with the organic insulating layer 12 in an area ARb of the aperture 13b, which is not covered with the lower electrodes LE2 and LE3. The partition 6 covers the aperture 13b.

Similarly to the lower electrode LE1, each of the lower electrodes LE2 and LE3 includes the metal layer ML, the first layer L1 which covers a lower surface of the metal layer ML, and the second layer L2 which covers an upper surface of the metal layer ML.

The inorganic insulating layer 13 plays a role of preventing the organic layers OR1, OR2, and OR3 from impregnating into moisture contained in the organic insulating layer 12. As a result, failure in light emission of the display elements DE1, DE2, and DE3 is suppressed. In addition, the apertures 13a and 13b plays a role of discharging moisture contained in the organic insulating layer 12, which is evaporated by heat treatment performed in the manufacturing processes of the display device DSP.

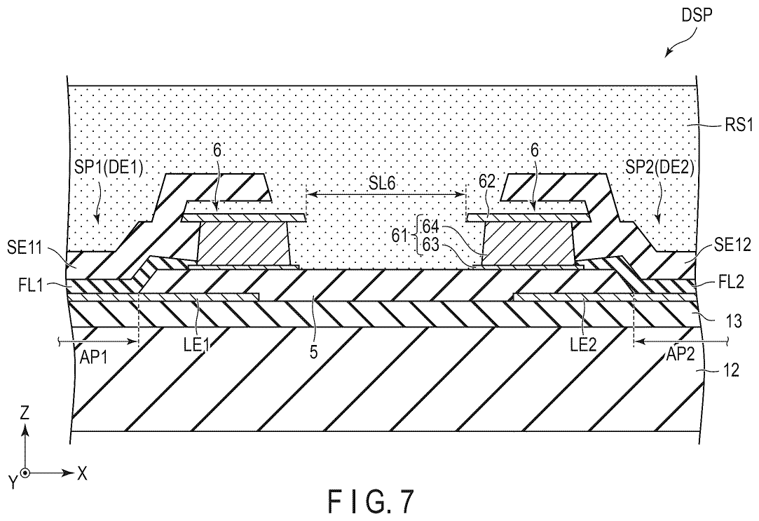

FIG. 7 is a schematic cross-sectional view showing a structure around the slit SL6. Incidentally, in FIG. 7, elements located under the organic insulating layer 12 and elements located above the resin layer RS1 are omitted.

In the example of FIG. 7, the slit SL6 is located between the lower electrodes LE1 and LE2. In addition, the slit SL6 does not overlap with the lower electrodes LE1 and LE2 in plan view. In the slit SL6, the rib layer 5 is in contact with the resin layer RS1.

Electronic devices on which the display device DSP is mounted may comprise an optical sensor such as an illumination sensor which detects external light. Such an optical sensor is provided on, for example, the back surface side (substrate 10 side) of the display device DSP. If the slit SL6 is provided in the partition 6, external light can pass through the slit SL6 and reach the optical sensor.

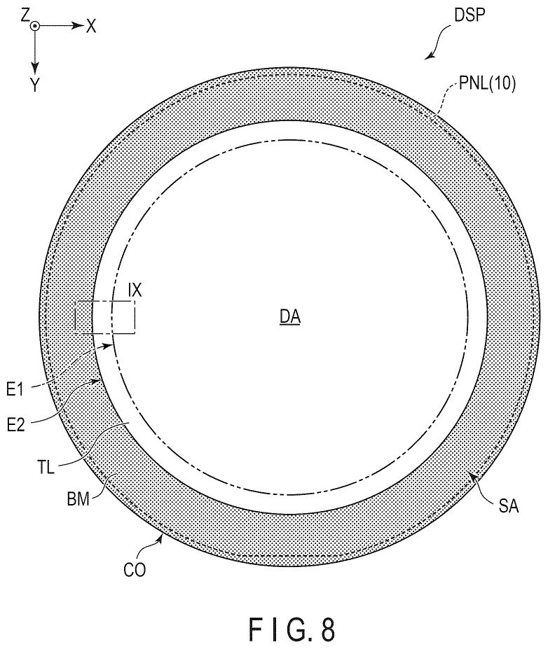

FIG. 8 is a schematic top view showing the display device DSP including the cover member CO. In the example of FIG. 8, the shape of the cover member CO in plan view is a circular shape.

The cover member CO includes a translucent portion TL which overlaps with the display area DA, and a light shielding portion BM which surrounds the translucent portion TL. The translucent portion TL is formed in a circular shape to cover the entire display area DA. In other words, the translucent portion TL covers a boundary E1 which is a boundary between the display area DA and the surrounding area SA and formed in a circular shape.

The light shielding portion BM overlaps with the surrounding area SA. A boundary E2 between the translucent portion TL and the light shielding portion BM is formed in a circular shape to overlap with the surrounding area SA. In the example of FIG. 8, the display panel PNL is entirely covered with the cover member CO, but a part of the display panel may not be covered with the cover member CO.

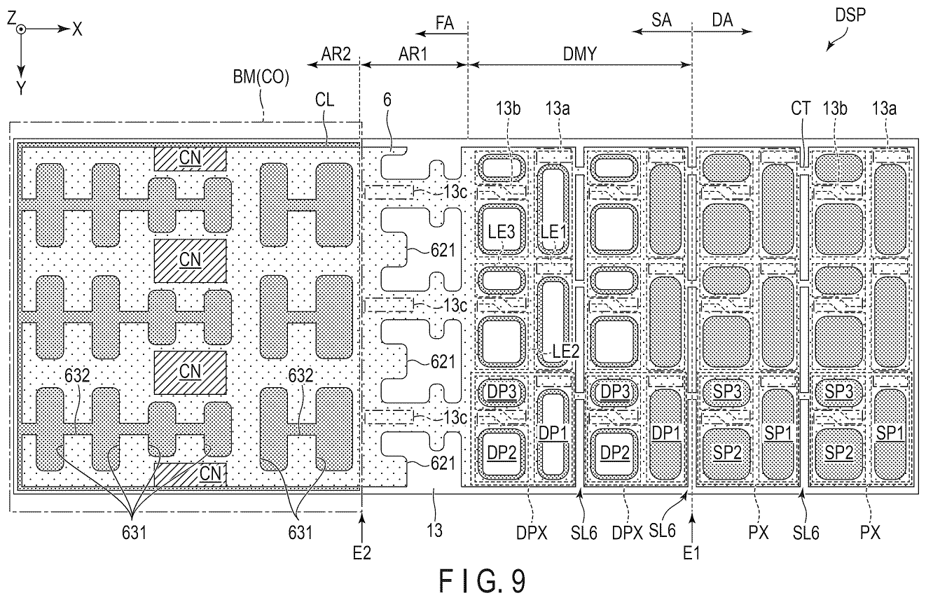

FIG. 9 is an enlarged plan view showing an area surrounded by frame IX in FIG. 8, in the display device DSP according to the first embodiment.

The surrounding area SA includes a dummy pixel area DMY and a frame area FA. The dummy pixel area DMY is adjacent to the display area DA to surround the display area DA. The frame area FA is adjacent to the dummy pixel area DMY to surround the dummy pixel area DMY.

A plurality of dummy pixels DPX are provided in the dummy pixel area DMY. For example, each dummy pixel DPX includes dummy subpixels DP1, DP2, and DP3. The dummy subpixels DP1, DP2, and DP3 have structures similar to those of the subpixels SP1, SP2, and SP3 shown in FIG. 2, respectively.

In other words, the dummy subpixel DP1 includes the lower electrode LE1, the organic layer OR1, the upper electrode UE1, and the sealing layer SE11. In addition, the dummy subpixel DP2 includes the lower electrode LE2, the organic layer OR2, the upper electrode UE2, and the sealing layer SE12. In addition, the dummy subpixel DP3 includes the lower electrode LE3, the organic layer OR3, the upper electrode UE3, and the sealing layer SE13.

However, the dummy subpixels DP1, DP2, and DP3 are configured not to emit light. For this reason, the dummy subpixels DP1, DP2, and DP3 display no images, unlike the subpixels SP1, SP2, and SP3.

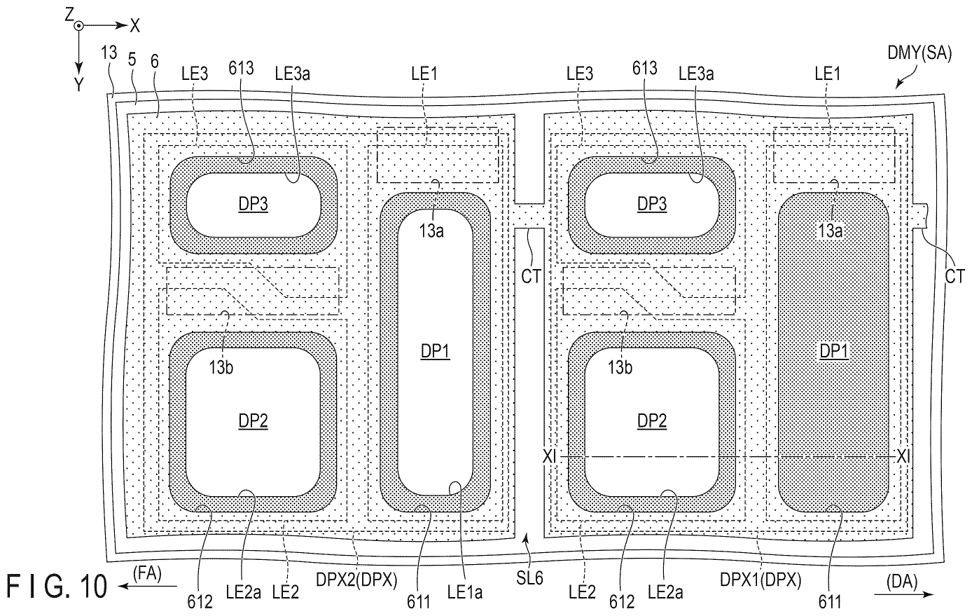

Some of the plurality of lower electrodes LE1, LE2, and LE3 provided in the dummy pixel area DMY include apertures (apertures LE1a, LE2a, and LE3a shown in FIG. 10). Details of the apertures will be described later.

In the example of FIG. 9, two columns in which the plurality of dummy pixels DPX are arranged in the Y-direction are arranged in the X-direction. Incidentally, three or more columns may be arranged in the X-direction. Alternatively, one column may be arranged.

A conductive layer CL located in the same layer as the lower electrodes LE1, LE2, and LE3 and formed of the same material as the lower electrodes LE1, LE2, and LE3 is provided in the frame area FA. In the present embodiment, the frame area FA includes a first area AR1 which does not overlap with the conductive layer CL and a second area AR2 which overlap with the conductive layer CL. The first area AR1 surrounds the display area DA and the dummy pixel area DMY and is adjacent to the dummy pixel area DMY. The second area AR2 surrounds the first area AR1 and is adjacent to the first area AR1.

The partition 6 is provided along the display area DA, the dummy pixel area DMY, and the frame area FA. In the dummy pixel area DMY, the partition 6 surrounds each of the dummy subpixels DP1, DP2, and DP3. The shape and layout of the apertures (apertures 611, 612, and 613 in FIG. 10) in the partition 6 in each of dummy subpixels DP1, DP2, and DP3 are similar to those of the apertures in the partition 6 in the subpixels SP1, SP2, and SP3. The slits SL6 and the connecting portion CT are also provided in the dummy pixel area DMY. In the example of FIG. 9, the boundary E1 overlaps with the slits SL6.

The partition 6 includes a plurality of apertures 621 (third apertures) in the first area AR1. The plurality of apertures 621 overlap with the inorganic insulating layer 13. In the example of FIG. 9, the plurality of apertures 621 are arranged in the Y-direction. Details of the apertures 621 will be described later.

The partition 6 includes a plurality of apertures 631 and slits 632 which connect the plurality of apertures 631, in the second area AR2. In the example of FIG. 9, the plurality of apertures 631 are arrayed in matrix. In addition, the slits 632 extend in the X-direction. Incidentally, the partition 6 may not include the slits 632. In other words, the plurality of apertures 631 may not be connected but arranged independently.

A plurality of contact portions CN are provided in the second area AR2. In the example of FIG. 9, the contact portions CN are arranged between the apertures 631 arranged in the Y-direction. The partition 6 is connected to the conductive layer CL vis the contact portions CN. The conductive layer CL is connected to the terminal portion T via power supply lines (not shown) and the like. The common voltage applied from the terminal portion T is applied to the upper electrodes UE1, UE2, and UE3 in the display area DA via the power supply lines, the conductive layer CL, and the partition 6.

The inorganic insulating layer 13 is provided over the display area DA, the dummy pixel area DMY, and the frame area FA. The apertures 13a and 13b are also provided in the dummy pixel area DMY. The inorganic insulating layer 13 further includes apertures 13c. The apertures 13c are provided in the first area AR1. In the example of FIG. 9, the apertures 13c are arranged between the apertures 621 arranged in the Y-direction.

In the example of FIG. 9, The light shielding portion BM of the cover member CO covers the second area AR2. In addition, the boundary E2 is located in the first area AR1. The plurality of dummy pixels DPX and the plurality of apertures 621 are provided between the boundaries E1 and E2.

Incidentally, the position of the boundary E2 is not limited to the example shown in FIG. 9. The position of the boundary E2 changes depending on position accuracy of attaching the cover member CO onto the display panel PNL, and tolerance. For this reason, the boundary E2 may be located in the second area AR2 or the dummy pixel area DMY.

FIG. 10 is a schematic plan view showing two dummy pixels DPX arranged in the X-direction, in the display device DSP according to the first embodiment. In this example, the dummy pixel DPX on the display area DA side, of two dummy pixels DPX arranged in the X-direction, is set as a dummy pixel DPX1, and the dummy pixel DPX on the frame area FA side is set as a dummy pixel DPX2. The dummy pixel DPX1 corresponds to the dummy pixel DPX adjacent to the display area DA. The dummy pixel DPX2 corresponds to the dummy pixel DPX adjacent to the frame area FA.

The partition 6 includes apertures 611, 612, and 613 (first apertures) that overlap with the lower electrodes LE1, LE2, and LE3, respectively, in the dummy pixel area DMY. The shape and layout of each of the apertures 611, 612, and 613 are similar to those of the aperture of the partition 6 in each of the subpixels SP1, SP2, and SP3.

At least a part of the lower electrodes LE1, LE2, and LE3 includes an aperture overlapping with any one of the apertures 611, 612, and 613. In the example of FIG. 10, the lower electrode LE1 included in the dummy pixel DPX1 does not include an aperture overlapping with the aperture 611. The lower electrode LE1 included in the dummy pixel DPX2 includes an aperture LE1a overlapping with the aperture 611. The lower electrode LE2 included in each of the dummy pixels DPX1 and DPX2 includes an aperture LE2a overlapping with the aperture 612. The lower electrode LE3 included in each of the dummy pixels DPX1 and DPX2 includes an aperture LE3a overlapping with the aperture 613. In other words, the lower electrode LE1 adjacent to the display area DA, of the lower electrodes LE1, LE2, and LE3, does not include the aperture LE1a overlapping with the aperture 611. The apertures LE1a, LE2a, and LE3a correspond to second apertures.

The rib layer 5 covers the entire dummy pixel area DMY. The rib layer 5 covers the apertures 611, 612, and 613 and the apertures LE1a, LE2a, and LE3a.

The inorganic insulating layer 13 covers the entire dummy pixel area DMY. The inorganic insulating layer 13 overlaps with the apertures 611, 612, and 613 and the apertures LE1a, LE2a, and LE3a in plan view. In the example of FIG. 10, the inorganic insulating layer 13 entirely covers the apertures 611, 612, and 613 and the apertures LE1a, LE2a, and LE3a.

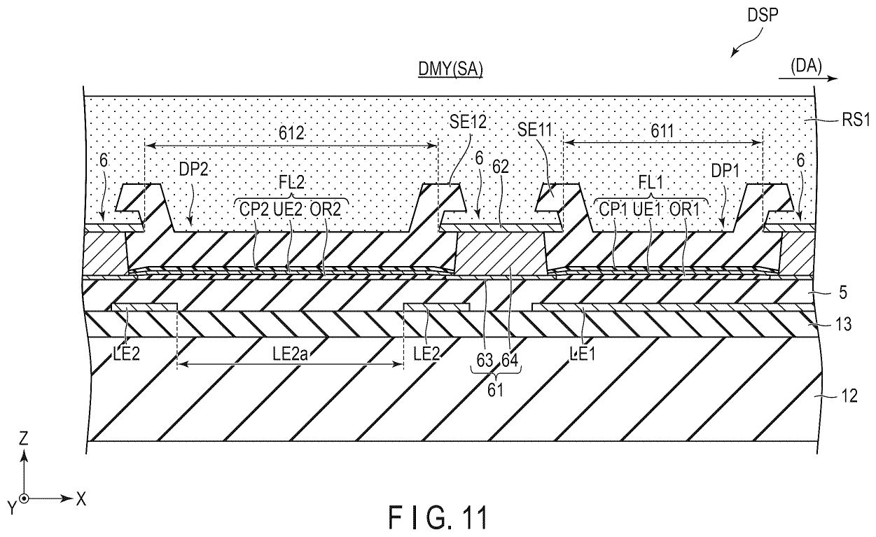

FIG. 11 is a schematic cross-sectional view showing the display device DSP along XI-XI line in FIG. 10. In the surrounding area SA, the organic insulating layer 12 is covered with the inorganic insulating layer 13. In addition, the lower electrodes LE1, LE2, and LE3 are provided on the inorganic insulating layer 13 and are covered with the rib layer 5. The rib layer 5 is in contact with the inorganic insulating layer 13 through the apertures LE1a, LE2a, and LE3a. The partition 6 is provided on the rib layer 5.

In the dummy subpixel DP1, the organic layer OR1 is provided on the rib layer 5, the upper electrode UE1 covers the organic layer OR1, the cap layer CP1 covers the upper electrode UE1, and the sealing layer SE11 covers the cap layer CP1. In the dummy subpixel DP2, the organic layer OR2 is provided on the rib layer 5, the upper electrode UE2 covers the organic layer OR2, the cap layer CP2 covers the upper electrode UE2, and the sealing layer SE12 covers the cap layer CP2. In the dummy subpixel DP3, the organic layer OR3 is provided on the rib layer 5, the upper electrode UE3 covers the organic layer OR3, the cap layer CP3 covers the upper electrode UE3, and the sealing layer SE13 covers the cap layer CP3.

The rib layer 5 does not include the pixel apertures AP1, AP2, and AP3 which overlap with the lower electrodes LE1, LE2, and LE3 in the dummy subpixels DP1, DP2, and DP3, respectively. In other words, the lower electrodes LE1, LE2, and LE3 are entirely covered with the rib layer 5. As a result, the rib layer 5 is interposed between the organic layers OR1, OR2, and OR3 and the lower electrodes LE1, LE2, and LE3, and the voltage which urges the organic layers OR1, OR2, and OR3 to emit light is not applied to the organic layers.

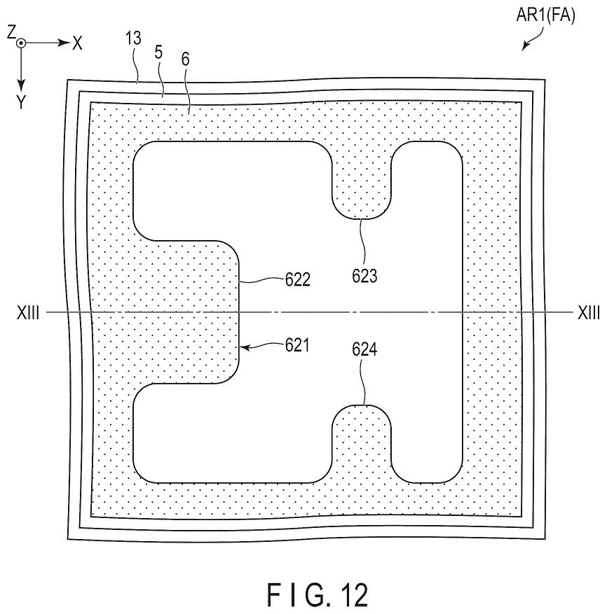

FIG. 12 is an enlarged plan view showing the aperture 621. In one example, recess portions 622, 623, and 624 are provided in the aperture 621. The recess portion 622 is formed in a concave shape in the X-direction. The recess portions 623 and 624 are formed in a concave shape in the Y-direction.

Incidentally, more recess portions may be provided in the aperture 621. In addition, at least one of the recess portions 622, 623, and 624 may be omitted in the aperture 621. The aperture 621 may be formed in, for example, a rectangular shape.

The area of the aperture 621 is larger than, for example, the area of each of the apertures 611, 612, and 613 and the apertures LE1a, LE2a, and LE3a shown in FIG. 10. However, the size of the aperture 621 is not limited to this example. For example, a plurality of apertures 621 having the area smaller than the area of each of the apertures 611, 612, and 613 and the apertures LE1a, LE2a, and LE3a may be provided in the first area AR1.

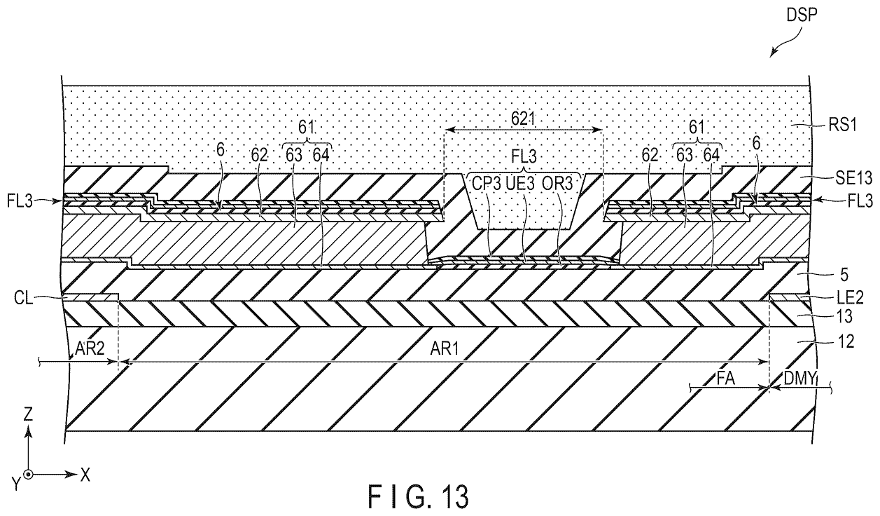

FIG. 13 is a schematic cross-sectional view showing the display device DSP along XIII-XIII line in FIG. 12. In the frame area FA, the organic insulating layer 12 is covered with the inorganic insulating layer 13. In addition, the conductive layer CL is provided on the inorganic insulating layer 13 and is covered with the rib layer 5. The rib layer 5 is in contact with the inorganic insulating layer 13 in the first area AR1.

In the frame area FA, the stacked film FL3 is provided on the rib layer 5 and the partition 6. The sealing layer SE13 continuously covers the stacked film FL3 provided on the rib layer 5 and the stacked film FL3 provided on the partition 6.

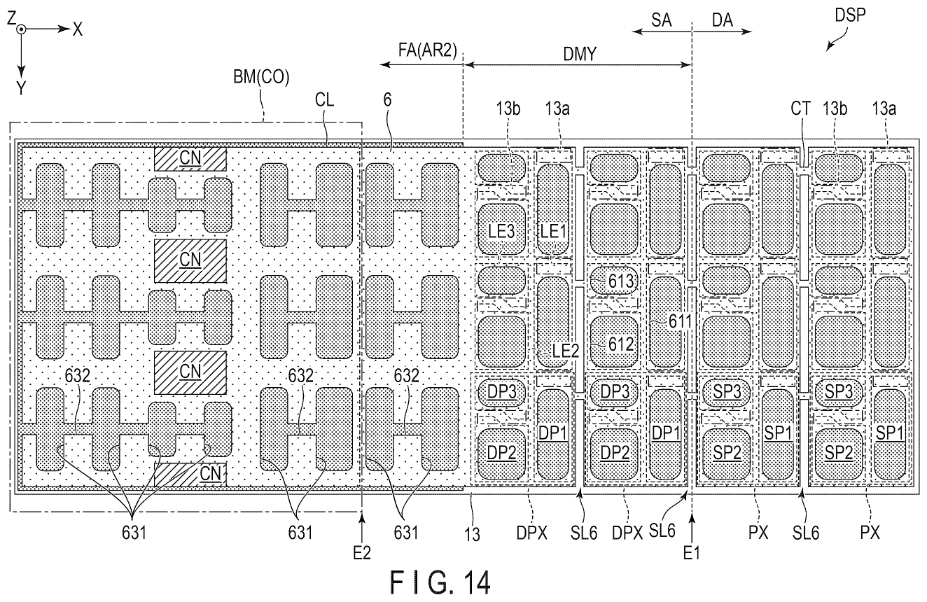

Next, the effect of the display device DSP of the present embodiment will be described using a display device DSP of a comparative example shown in FIG. 14.

FIG. 14 is a schematic plan view showing the display device DSP according to the comparative example. The plan view of FIG. 14 is a view corresponding to the plan view of FIG. 9.

The lower electrodes LE1, LE2, and LE3 of the display device DSP of the comparative example do not include the apertures LE1a, LE2a, and LE3a, respectively. For this reason, in the dummy pixel area DMY, the apertures 611, 612, and 613 are covered with the lower electrodes LE1, LE2, and LE3, respectively.

In addition, the partition 6 of the display device DSP of the comparative example does not include the aperture 621. Furthermore, an entire surface of the frame area FA is covered with the conductive layer CL. For this reason, the frame area FA does not include the first area AR1 shown in FIG. 9. Therefore, the second area AR2 is adjacent to the dummy pixel area DMY.

In such a configuration, an area excluding the slit SL6, in the area between the boundary E1 and the boundary E2, is covered with one of the lower electrodes LE1, LE2, and LE3, the conductive layer CL, and the partition 6. In addition, each of the lower electrodes LE1, LE2, and LE3, the conductive layer CL, and the partition 6 includes a layer formed of metal. For this reason, it is difficult to recognize the boundary E1 and the boundary E2 due to the light reflection on the lower electrodes LE1, LE2, and LE3, the conductive layer CL, and the partition 6, and the like.

As a result, for example, when the cover member CO is applied to the display panel PNL, in the process of manufacturing the display device DSP, accuracy in alignment may be worsened. In addition, when the displacement between the display panel PNL and the cover member CO is measured after applying the cover member CO to the display panel PNL, in the process of inspecting the display device DSP, variation in measurement may become greater. For this reason, the yield of the display device DSP may be degraded.

Incidentally, the slit 6 which does not overlap with the lower electrodes LE1, LE2, and LE3, the conductive layer CL, or the partition 6 is provided in a region between the boundary E1 and the boundary E2. The area of the slit SL6 is remarkably smaller than the area of the region. For this reason, the slit 6 has little contribution to the improvement in visibility of the boundary E1 and the boundary E2.

In the present embodiment, at least some of the lower electrodes LE1, LE2, and LE3 provided in the dummy pixel area DMY include the apertures LE1a, LE2a, and LE3a which overlap with the apertures 611, 612, and 613 of the partition 6. For this reason, the area of the region which is not covered with the lower electrodes LE1, LE2, and LE3, the conductive layer CL, or the partition 6, of the region between the boundary E1 and the boundary E2, is larger than the area of the region of the display device DSP of the comparative example. The visibility of the boundary E1 and the boundary E2 is thereby improved. The accuracy in alignment of the display panel PNL and the cover member CO is therefore improved. In addition, the variation in measurement of the displacement between the display panel PNL and the cover member CO can be suppressed. The yield of the display device DSP can be thereby improved.

Furthermore, in the present embodiment, the aperture 621 of the partition 6 is formed in the first area AR1 where the conductive layer CL is not provided. For this reason, the area of the region which is not covered with the lower electrodes LE1, LE2, and LE3, the conductive layer CL, or the partition 6, of the region between the boundary E1 and the boundary E2, is further increased. Therefore, the effects such as the improvement of the accuracy in alignment and the suppression of the variation in measurement can be obtained.

As the area of the region which is not covered with the lower electrodes LE1, LE2, and LE3, the conductive layer CL, or the partition 6 increases, higher effects can be obtained. For this reason, the effects can be made higher by making the first area AR1 wider than the example of FIG. 9 and further providing a plurality of apertures 621. Incidentally, in this case, the conductive layer CL or the partition 6 is desirably provided just above the thin film transistor included in the circuit layer 11. The change in the characteristics of the transistor, which is caused by light entering the transistor, can be thereby suppressed.

Incidentally, the lower electrodes LE1, LE2, and LE3 are patterned by etching during the process of manufacturing the display device DSP. When a plurality of elements are thus formed simultaneously by etching, the outermost part of these elements may be excessively eroded. For this reason, the lower electrodes LE1, LE2, and LE3 in the outermost circumference in the display area DA may be excessively eroded by etching, and the display quality may be degraded.

In the present embodiment, the dummy pixel DPX including the lower electrodes LE1, LE2, and LE3 is provided in the dummy pixel area DMY adjacent to the display area DA. For this reason, the excessive erosion of the lower electrodes LE1, LE2, and LE3 in the outermost circumference in the display area DA can be suppressed, and the display quality can be improved. In addition, the lower electrodes LE1, LE2, and LE3 which are adjacent to the display area DA do not include the apertures LE1a, LE2a, and LE3a, respectively. For this reason, the above-mentioned corrosion can be suppressed.

In addition, in the present embodiment, the area where the apertures 611, 612, and 613 overlap with the apertures LE1a, LE2a, and LE3a, and the aperture 621, are covered with the inorganic insulating layer 13. As a result, entry of moisture contained in the organic insulating layer 12 to a layer upper than the inorganic insulating layer 13 can be suppressed.

### Second Embodiment

Next, a display device DSP of a second embodiment will be described. The elements which are the same as or similar to the elements of the first embodiment are denoted by the same reference numerals, and duplicated descriptions are omitted as appropriate.

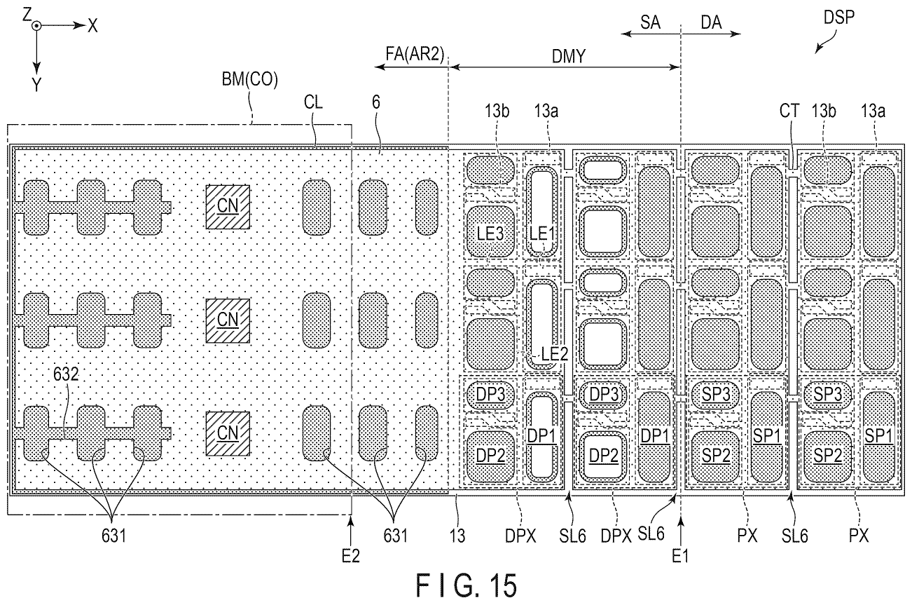

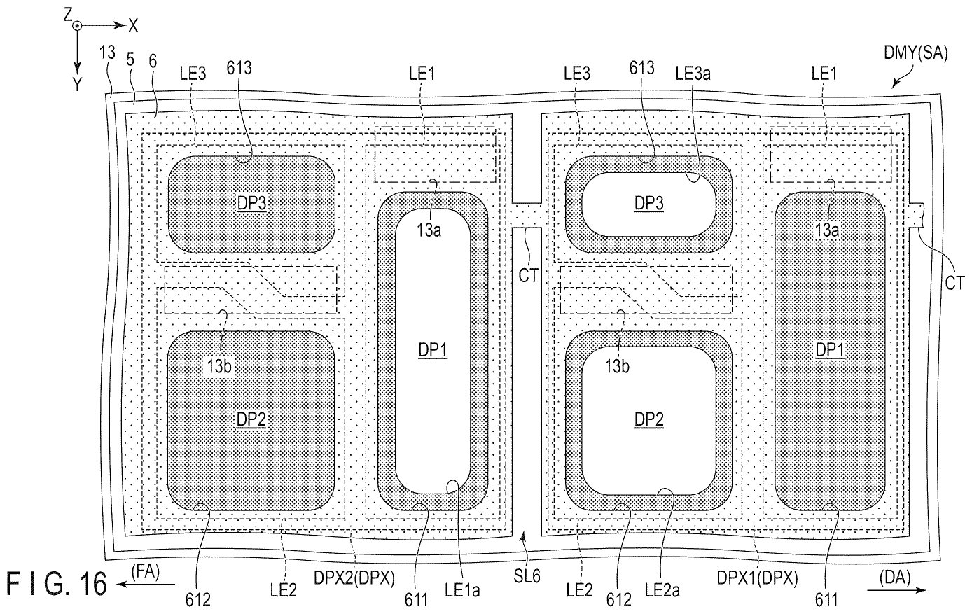

FIG. 15 is an enlarged plan view showing an area surrounded by frame IX in FIG. 8, in the display device DSP according to the second embodiment. FIG. 16 is a schematic plan view showing two dummy pixels DPX arranged in the X-direction, in the display device DSP according to the second embodiment.

As shown in FIG. 15 and FIG. 16, the lower electrode LE2 of the dummy pixel DPX2 which is adjacent to the frame area FA does not include the aperture LE2a overlapping with the aperture 612, in the display device DSP of the second embodiment. For this reason, the aperture 612 which is adjacent to the frame area FA is covered with the lower electrode LE2. In addition, the lower electrode LE3 of the dummy pixel DPX2 which is adjacent to the frame area FA does not include the aperture LE3a overlapping with the aperture 613. For this reason, the aperture 613 which is adjacent to the frame area FA is covered with the lower electrode LE3.

Furthermore, as shown in FIG. 15, the partition 6 provided in the frame area FA does not include the aperture 621, in the display device DSP of the second embodiment. In addition, an entire surface of the frame area FA is covered with the conductive layer CL. For this reason, the frame area FA does not include the first area AR1 shown in FIG. 9. Therefore, the second area AR2 is adjacent to the dummy pixel area DMY.

In addition, as shown in FIG. 15, the partition 6 includes a plurality of apertures 631 connected by slits 632, and a plurality of apertures 631 which are not connected by the slits 632 but are provided independently, in a second area AR2. Contact portions CN are provided between the apertures 631 arranged in the X-direction. Incidentally, the arrangement of the apertures 631, the slits 632, and the contact portions CN may be the same as the example shown in FIG. 9 or may be different from the examples shown in FIG. 9 and FIG. 15.

Focus on a plurality of dummy pixels DPX arranged in the X-direction will be made here. In the second embodiment, the number of each of the lower electrodes LE1, LE2, and LE3 including the apertures LE1a, LE2a, and LE3a is one. In addition, the partition 6 does not include the aperture 621 provided in the first area AR1. For this reason, in the second embodiment, the area of the region which is not covered with the lower electrodes LE1, LE2, and LE3, the conductive layer CL, or the partition 6, of the region between the boundary E1 and the boundary E2, is smaller than the area of the region of the first embodiment, but larger than the area of the region of the comparative example. For this reason, the boundary E1 and the boundary E2 can also be visually recognized in this configuration.

The same effects as those obtained in the display device DSP according to the above-described first embodiment can also be obtained in the display device DSP according to the second embodiment.

All of display devices that can be implemented by a person of ordinary skill in the art through arbitrary design changes to the display devices described above as embodiments of the present invention come within the scope of the present invention as long as they are in keeping with the spirit of the present invention.

Various modified examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device comprising:
a substrate including a display area where images are displayed, and a dummy pixel area which includes a plurality of dummy subpixels where images are not displayed, which surrounds the display area, and which is adjacent to the display area;
a plurality of lower electrodes located above the substrate and provided in the dummy pixel area; and
a partition which includes a lower portion provided above the lower electrode and an upper portion provided on the lower portion to protrude from a side surface of the lower portion, and which is provided across the display area and the dummy pixel area, wherein
each of the plurality of dummy subpixels includes the lower electrode,
the partition includes a first aperture overlapping with the lower electrode, and
at least a part of the plurality of lower electrodes includes a second aperture overlapping with the first aperture.

2. The display device of claim 1, further comprising:
a cover member including a translucent portion overlapping with the display area and a light shielding portion surrounding the translucent portion, and located above the partition.

3. The display device of claim 2, wherein
a boundary between the translucent portion and the light shielding portion is located outside the display area in plan view.

4. The display device of claim 1, wherein
the lower electrode adjacent to the display area, of the plurality of lower electrodes, does not include the second aperture.

5. The display device of claim 1, further comprising:
a rib layer provided across the display area and the dummy pixel area, covering the lower electrodes in the dummy pixel area, and formed of an inorganic material, wherein
the partition is provided on the rib layer.

6. The display device of claim 5, wherein
the rib layer covers the first aperture and the second aperture in plan view.

7. The display device of claim 1, further comprising:
a conductive layer located in a same layer as the lower electrode and formed of a same material as the lower electrode, wherein
the substrate further includes a frame area which surrounds the dummy pixel area, which is adjacent to the dummy pixel area, and where the partition and the conductive layer are provided,
the frame area includes a first area which does not overlap with the conductive layer, and
the partition includes a third aperture provided in the first area.

8. The display device of claim 7, wherein
the first area surrounds the dummy pixel area and is adjacent to the dummy pixel area.

9. The display device of claim 7, wherein
an area of the third aperture is larger than an area of each of the first aperture and the second aperture.

10. The display device of claim 1, further comprising:
an organic insulating layer located between the substrate and the lower electrode, and provided across the display area and the dummy pixel area; and
an inorganic insulating layer covering the organic insulating layer and being in contact with a lower surface of the lower electrode.

11. The display device of claim 10, wherein
the inorganic insulating layer covers the first aperture and the second aperture.

12. The display device of claim 10, further comprising:
a rib layer provided across the display area and the dummy pixel area, covering the lower electrodes in the dummy pixel area, being in contact with the inorganic insulating layer through the second aperture, and formed of an inorganic material, wherein
the partition is provided on the rib layer.

13. The display device of claim 10, further comprising:
a conductive layer located in a same layer as the lower electrode and formed of a same material as the lower electrode, wherein
the substrate further includes a frame area which surrounds the dummy pixel area, which is adjacent to the dummy pixel area, and where the partition and the conductive layer are provided,
the frame area includes a first area which does not overlap with the conductive layer, and
the partition includes a third aperture provided in the first area and covered with the inorganic insulating layer.

14. The display device of claim 13, further comprising:
a rib layer provided across the display area and the dummy pixel area, covering the lower electrodes in the dummy pixel area, being in contact with the inorganic insulating layer through the third aperture, and formed of an inorganic material, wherein
the partition is provided on the rib layer.

15. The display device of claim 1, wherein
the partition includes a plurality of slits provided in the display area and the dummy pixel area to extend in a single direction, and
the plurality of slits do not overlap with the low electrode in plan view.

16. The display device of claim 5, wherein
each of the dummy subpixels further includes:
an organic layer provided on the rib layer;
an upper electrode covering the organic layer;
a cap layer covering the upper electrode; and
a sealing layer covering the cap layer and formed of an inorganic insulating material.

17. A display device comprising:
a substrate having a display area where images are displayed and a surrounding area provided outside the display area;
a conductive layer located above the substrate and provided in the surrounding area; and
a partition which includes a lower portion provided above the conductive layer, and an upper portion provided on the lower portion to protrude from a side surface of the lower portion, and which is provided across the display area and the surrounding area, wherein
the partition includes a first aperture overlapping with the conductive layer, and
the conductive layer includes a second aperture overlapping with the first aperture.

18. The display device of claim 17, wherein
the surrounding area includes a dummy pixel area including a plurality of dummy subpixels where images are not displayed, surrounding the display area, and being adjacent to the display area, and a frame area surrounding the dummy pixel area and being adjacent to the dummy pixel area, and
the first aperture and the second aperture are provided in the dummy pixel area.

19. The display device of claim 18, wherein
the frame area includes a first area which does not overlap with the conductive layer, and
the partition includes a third aperture provided in the first area.

20. The display device of claim 17, further comprising:
a cover member including a translucent portion overlapping with the display area and a light shielding portion surrounding the translucent portion, and located above the partition, wherein
a boundary between the translucent portion and the light shielding portion overlaps with the surrounding area in plan view.
